(19) United States
(12) Patent Application Publication
(10) Pub. No.: US 2001/0046166 A1
(43) Pub. Date: Nov. 29, 2001

(54) Digital memory circuit

(76) Inventors: Helmut Fischer, Taufkirchen (DE); Gunnar Krause, Munchen (DE)

Correspondence Address: LERNER AND GREENBERG, P.A., Post Office Box 2480, Hollywood, FL, 33022-2480, US

(21) Appl. No.: 09/867,256

(22) Filed: May 29, 2001

(30) Foreign Application Priority Data
May 29, 2000 (DE) 100 26 654.1

(51) Int. Cl. G11C 7/00

(52) U.S. Cl. 365/200

(57) ABSTRACT

In addition to regular rows and columns of memory cells, the matrix-like memory cell array of the digital memory circuit, also has redundant rows of memory cells so as to replace faulty regular rows. In the case of at least one subset of the columns, wires of column lines used for accessing the memory cells intersect one another at locations between the edges of the cell array which are parallel to the rows, so that the data topology changes at these locations. The redundant rows of memory cells form separate subsets arranged in regions of different data topology of the cell array, such that, for each data topology, a subset of the redundant rows is available with an appropriate data topology.

### BACKGROUND OF THE INVENTION

1. Field of the Invention

The invention lies in the memory technology field and relates, more specifically, to a digital memory circuit containing one or more arrays of memory cells in a matrix-like arrangement. The primary, but not exclusive, area of application of the invention is digital semiconductor memories, such as DRAM memories, in which the memory cells are formed by electrical capacitances whose charge state represents the memory content.

Digital solid state memories, such as the aforementioned semiconductor memories, usually contain one or more matrix-like arrangements comprising X times Y memory cells. To be able to address any desired memory cell in such a matrix for the purpose of writing or reading an information item, rows and columns are defined in the matrix as follows: the rows are Y disjunctive subsets of memory cells, each comprising X elements connected to a common row line; the columns are X disjunctive subsets of memory cells, each comprising Y elements connected to a common column line. Each memory cell can thus be uniquely addressed by driving a particular row line and selecting a particular column. To write or read an information item on a desired memory cell, the row line associated with the row containing the relevant cell is activated by applying a particular level from a row address decoder, as a result of which all the cells in that row are prepared for possible access (row addressing). The actual access is then effected using that instance of the column lines which is associated with the column containing the desired cell. For writing, a level representing the information item which is to be written is applied to the relevant column line; for reading, the level which is stored in the desired cell and, on account of the activated row line, is coupled to the relevant column line from this memory cell is sensed on this column line. Usually, a separate write/read circuit is provided for each column of the memory matrix, and these circuits can be driven selectively by a column address decoder in order to select a respectively desired column line for applying or sensing the information level (column addressing).

In most cases, the memory cells are binary, i.e. they are designed to store one bit each. Since the column lines are those which transfer the memory bits to and from the cells, they are also called “bit lines”, while the row lines are generally also called “word lines.”

The physical layout of the rows and columns and of the write/read circuits of a memory matrix may differ from case to case. Usually, the write/read circuits are arranged next to one another as one or more rows running transversely with respect to the column direction. They can either form a single block or two blocks, each running outside the matrix along one or both of the edges of the cell array forming the matrix which are parallel to the rows. The block of write/read circuits can also run transversely through the center of the matrix, so that each column of memory cells and the associated column line comprises two sections extending from the relevant write/read circuit in opposite directions. In this case, the matrix no longer forms a cohesive structure without gaps, but instead is split into two cell arrays. In high capacity memory banks, a plurality of blocks of write/read circuits are usually provided which, spaced apart in the column direction, extend transversely through the matrix and are each responsible for individual column sections. In this case, more than two multirow segments are produced in the column direction, each of which separately forms a cohesive cell array.

Following manufacture, a memory matrix may contain faults, either in the memory cells themselves or on the row and column lines. To overcome this problem, it is customary to test the matrix before it is used further and to replace those rows and columns in which a fault has been found with a row or column without any faults. To provide this repair option, the matrix is equipped, during actual manufacture, with “redundant” rows and columns in addition to the “regular” rows and columns whose number determines the nominal memory capacity.

Repair, that is to say replacement of a faulty regular row, for example, with a redundant row, can be effected, by way of example, by suppressing decoding of the row line for the faulty row during operation and, instead, activating the row line for a redundant row. A faulty column can be replaced on the basis of a similar principle. These operations are usually carried out by laser irradiation on “fuse banks.”

In the case of digital memory circuits, in particular in the case of DRAM memories, it is customary for the column lines to be of two-wire design in the form of “bit line pairs.” In that case, it is a conventional practice to arrange the layout such that the wires of at least one subset of the column lines intersect one another at certain locations. This “bit line twist,” as disclosed, for example, in U.S. Pat. No. 5 461 589 is intended to reduce parasitic couplings between adjacent column lines.

It has now been found that any bit line twists that are present can cause problems with regard to the replacement of faulty rows with redundant rows. This is because each twist causes the data topology on the far side of the relevant twist area to be different than on the near side. The term “data topology” denotes the pattern in which the two wires of the individual column lines are associated with the row lines, which also determines the physical polarity of the data stored in the cells. If a redundant row connected as replacement for a faulty regular row does not have the same data topology, problems may arise particularly when testing the memory.

### SUMMARY OF THE INVENTION

The object of the present invention is to provide a novel digital memory circuit which overcomes the above-noted deficiencies and disadvantages of the prior art devices and methods of this general kind, and which eliminate specifically the foregoing problems.

With the above and other objects in view there is provided, in accordance with the invention, a digital memory circuit, comprising:

at least one cell array with a multiplicity of memory cells in a matrix arrangement of rows and columns, the cell array having edges extending parallel to the rows;

the rows and columns including regular rows and regular columns defining a nominal memory capacity of the cell array, and redundant rows of memory cells replacing faulty regular rows;

the columns having at least one subset of columns wherein wires of column lines used for accessing the memory cells intersect one another at locations between the edges of the cell array parallel to the rows, thereby changing a data topology changes at the locations; and

the redundant rows of memory cells forming separate subsets arranged in regions of different data topology in the cell array, such that, for each data topology, a subset of the redundant rows is available with a corresponding data topology.

In other words, the subject matter of the invention is a digital memory circuit having at least one cell array which contains a multiplicity of memory cells in a matrix-like arrangement of rows and columns. In addition to regular rows and columns of memory cells, redundant rows of memory cells are provided as replacement for faulty regular rows. In the case of at least one subset of the columns, wires of column lines used for accessing the memory cells intersect one another at locations between the edges of the cell array which are parallel to the rows, so that the data topology changes at these locations. The redundant rows of memory cells form separate subsets arranged in regions of different data topology of the cell array, such that, for each data topology, a subset of the redundant rows is available with an appropriate data topology.

The invention has the advantage that faulty regular rows can be repaired with the correct topology in all cases. That is to say that suitable circuit means can ensure that faulty regular rows are in each case replaced with a redundant row having an appropriate data topology. The redundant rows of each subset can be arranged anywhere within the region of the relevant topology, but there are particularly advantageous arrangements, as explained below.

In accordance with an added feature of the invention, at least some elements of each subset of redundant rows arranged in a region adjacent to a respective the edge of the cell array extending parallel to the rows are arranged directly adjacent to the edge.

If the locations of all existing twists are limited to a single area between two adjacent rows, e.g. to an area in the center of the cell array which is parallel to the rows, then there are only two areas of different data topology. In this case, in this preferred embodiment of the invention, the redundant rows are arranged in the form of separate blocks at the two opposite edges of the cell array which are parallel to the rows. An important and surprising advantage of this feature is that the average frequency of the occurrence of faults requiring repair is reduced. This is because it has been found that faults arise with a greater degree of likelihood at places where there are irregularities in the otherwise regular structure of a memory matrix. The outer edges of the matrix, and also the edges of the individual segments, represent such irregularities, because the regular (more or less “homogeneous”) structure of the cell array ends or is noticeably interrupted at these locations. Thus, the edges of the cell arrays are found to be more prone to repair than the core area for technological reasons. If the redundant instances of row and/or column lines are now distributed over two blocks at the two opposite edges of the cell array, the number of regular instances close to the edge, and hence the likelihood of faults on regular rows and columns, falls. Thus, the number of repairs also falls. Any faults are instead distributed more over the redundant instances. Although faulty redundant rows and columns can no longer be used for repair, they for their part do not give rise to any repair requirement. The economic viability is thus increased overall. A similar advantage can also be attained if one or more instances of the redundant rows of one and/or other subset are arranged directly adjacent to the twist area, because here too there is a certain interruption in the more or less homogeneous structure of the cell array, which can increase the likelihood of a fault.

In accordance with an additional feature of the invention, at least some elements of each subset of redundant rows arranged in a region between two adjacent areas extending parallel to the rows, in which areas column line wires intersect one another, are disposed directly adjacent to at least one of the areas.

In accordance with a concomitant feature of the invention, the rows and columns further include a plurality of redundant columns of memory cells replacing faulty regular columns; and the redundant columns are arranged as two separate blocks at mutually opposite edges of the cell array extending parallel to the columns.

If the cell array also contains a plurality of redundant columns of memory cells, the redundant columns can likewise form two separate blocks arranged at the two opposite edges of the cell array which are parallel to the columns. The arrangement of redundant rows or columns at both opposite edges of a cell array in each case has to date been proposed only for cell arrays without a bit line twist (see for example German published patent application DE 199 33 894 A1).

It is frequently desirable to provide a plurality of spaced twist areas between the edges which are parallel to the rows, the column line wires which intersect one another in the various twist areas not being identical. In this case, it is not sufficient to provide redundant rows only at the two edges of the cell array, because in such cases there are more than two different data topologies and, accordingly, also more than two regions of different data topology, some of which are situated between adjacent twist areas. Such regions contain redundant row lines preferably directly adjacent to one and/or other of the adjacent twist areas.

Other features which are considered as characteristic for the invention are set forth in the appended claims.

Although the invention is illustrated and described herein as embodied in a digital memory circuit, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a schematic detail of a cell array having a single twist area; and

FIG. 2 is a schematic detail of a cell array having three twist areas.

### DESCRIPTION OF THE PREFERRED EMBODIMENTS

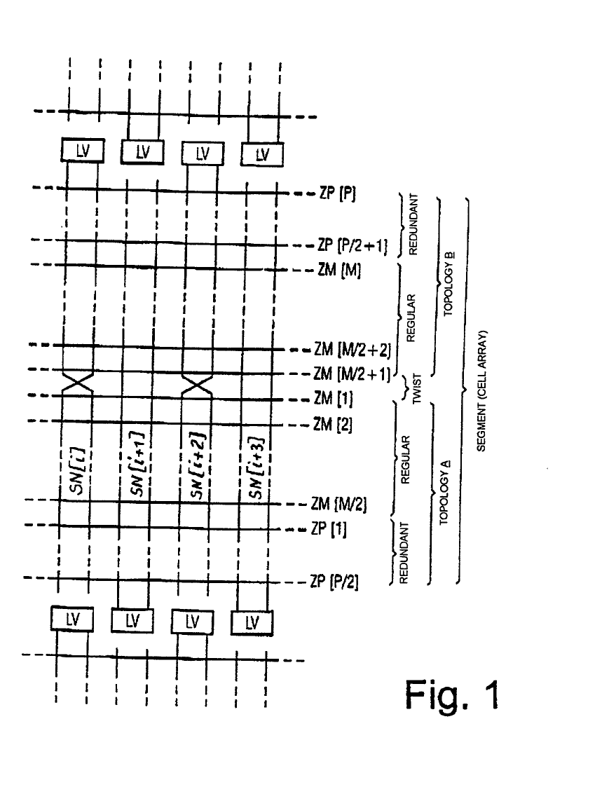

Referring now to the figures of the drawing in detail and first, particularly, to FIG. 1 thereof, there is seen a cell array with a large multiplicity of memory cells arranged in the manner of a rectangular matrix. For reasons of clarity in the drawing, the memory cells themselves are not shown; only the row and column lines used for accessing the cells are shown, as horizontal and vertical lines. The memory cells can be thought of as elements associated with individual points of intersection between the row and column lines. Each group of memory cells associated with a common row line is called a “row” below. Similarly, each group of memory cells associated with a common column line is called a “column.” The drawing shows the reference symbols for the rows and columns on the relevant row and column lines in each case.

The cell array shown in fragments in the drawing is a “segment” of a memory bank and contains a number M of regular rows ZM[1] to ZM[M] and a number P of redundant rows ZP[1] to ZP[P]. The cell array is situated between two blocks of sense amplifiers LV which form component parts of the write/read circuits of the memory bank. These blocks each extend parallel to the rows and thus delimit the aforementioned cell array at the “upper” and “lower” edges. As indicated in the drawing, other similar cell arrays may be situated on the far side of the blocks of sense amplifiers LV if the memory bank comprises a plurality of segments (as is usually the case in practice). In a typical embodiment, a segment can comprise, by way of example, M=1024 regular rows and P=24 redundant rows.

The cell array under consideration, comprising M+P rows, (and possibly also the other similar cell arrays) contains N regular columns SN[1] to SN[N]. The product of M and N determines the nominal memory capacity of the cell array (in bits if binary memory cells are involved). The detail illustrated shows the cell array only over part of its width, comprising four central instances SN[i] to SN[i+3] of the columns. The column lines of the individual columns have two wires, and each wire pair (bit line pair) is connected to a respective associated sense amplifier LV. In the case illustrated, each second bit line, that is to say each second wire pair, is connected to alternate instances of those sense amplifiers LV which are situated in the block along one edge of the cell array. Similarly, the column lines situated in between are connected to alternate instances of the sense amplifiers on the other side of the cell array. The rest of the sense amplifiers LV of the two blocks are associated with the cell arrays of the adjacent segments of the memory bank. This association between column lines and sense amplifier blocks is not imperative, however, but is in line with customary practice.

In the exemplary embodiment shown in FIG. 1, the (or each) cell array is provided with a “bit line twist” such that, in the center of the array, within an area between two rows which extends transversely with respect to the columns, the wires of some column lines intersect one another. In the case of FIG. 1, such a twist exists in every other column. This is only one example, however; other patterns are also possible. The result of each twist pattern is that the association between the wires of the column lines and the row lines has a different arrangement on one side of the twist area than on the other side. The twist thus produces two regions of different “data topology” A and B.

During operation, the row lines are driven selectively by a row address decoder using associated drivers, and the associated sense amplifiers are selected selectively by a column address decoder for the purpose of writing or reading an information item on that memory cell which is associated with the driven row line and with the column determined by the selected sense amplifier. The circuits used for this purpose are generally known and are not shown separately in the drawing; the associated connections on the sense amplifiers have likewise been omitted.

In the case of the exemplary embodiment shown in FIG. 1, one half ZP[1] to ZP[P/2] of the P redundant rows forms a first “redundancy block” at the lower edge of the cell array, and the other half ZP[P/2+1] to ZP[P] forms a second redundancy block at the upper edge. This means that the redundant rows, at the two edges of the cell array which are parallel to the rows, are the closest elements to the edge in the total quantity of M+P rows. The result of splitting the redundant rows ZP[1] to ZP[P] over two separate blocks at the upper and lower edges of the cell array in such a manner is that each region of the data topology A or B contains redundant rows of the same topology, so that, in the event of a fault in a regular row of one or other topology, a redundant row of similar topology is available as replacement in each case.

Another advantage of the configuration shown in FIG. 1 is that the regular rows ZM[1] to ZM[M] are less prone to faults, as mentioned further above, because none of these rows is situated in the edge area of the cell array. A corresponding advantage can also be attained in relation to the columns if the cell array is equipped with redundant columns as replacement for faulty regular columns, and the redundant columns are split into two separate blocks at opposite edges of the cell array which are parallel to the columns (not shown in the drawing), which means that the regular columns are less prone to faults.

The two subsets of redundant rows do not necessarily have to be arranged at the two outer edges of the cell array, however, but instead may in principle be situated at any desired points in the respective region of the relevant data topology. This means that, if only one twist area exists, as in the case in FIG. 1, the two subsets of redundant rows can be situated anywhere on both sides of an existing twist area. Although this may compromise the advantage mentioned further above of reduced proneness to faults, the invention is not limited to the edge position of the redundant rows which is shown in FIG. 1.

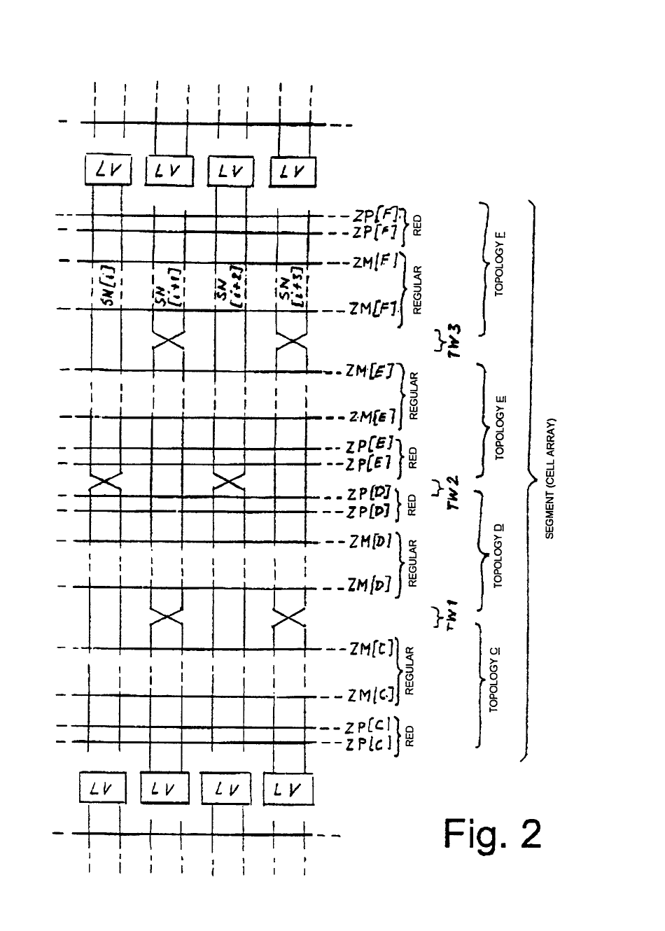

Referring now to FIG. 2, there is shown an example of the split of redundant rows in a cell array having a plurality of spaced twist areas. The configuration shown differs from that shown in FIG. 1 in that not only are the column line wires of every other column SN[i], SN[i+2], etc. twisted in a twist area TW2 in the center of the cell array, but rather the column lines in the columns SN[i+1], SN[i+3], etc. situated in between are also twisted, specifically twice in each case. Two further twist areas TW1 and TW3 thus exist, with TW1 being situated in the center between TW2 and the “lower” edge of the cell array which is parallel to the rows, and with TW3 being situated in the center between TW2 and the “upper” edge of the cell array which is parallel to the rows.

The result of the twist pattern shown in FIG. 2 is that there are four regions of different data topology. The region between the lower edge and the twist area TW1 has the topology C. The twists in the area TW1 result in a different topology D arising on the far side of TW1. Similarly, the regions between TW2 and TW3 and between TW3 and the upper edge of the cell array have particular topologies E and F, respectively, which differ both from one another and from the topologies C and D.

In line with the four different data topologies C, D, E and F, the total quantity of the regular rows is divided into four subsets whose topology is different and whose elements are denoted by ZM[C], ZM[D], ZM[E] and ZM[F] in FIG. 2. According to the invention, to be able to replace any desired regular rows ZM with a redundant row ZP of respectively appropriate topology, the total quantity of the redundant rows ZP is likewise split into four subsets, whose elements are denoted by ZP[C], ZP[D], ZP[E] and ZP[F]. Each of these four subsets is situated in a different one of the four different topology regions.

To simplify illustration, FIG. 2 shows only two redundant rows in each topology region. The redundant rows ZP[C] of topology C are situated preferably as a block directly adjacent to the lower edge of the cell array, and the redundant rows ZP[F] of topology C are situated preferably as a block directly adjacent to the upper edge of the cell array. This has the aforementioned advantage that the regular rows are at the greatest possible distance from the edges of the cell array which are parallel to the rows, and hence the likelihood of faults is minimized for regular rows. The redundant rows ZP[E] of topology E and the redundant rows ZP[F] of topology F are situated preferably as blocks directly adjacent to a respective twist area, on both sides of the twist area TW2 in the case shown. This reduces the number of regular rows close to twists, which are sometimes more prone to faults than rows which are remote from twists.

The invention is naturally not limited to the position shown in FIG. 2 for redundant rows ZP within the respective topology region. In principle, the primary purpose of the invention, namely the opportunity for repair with the correct topology, is achieved with any desired arrangement of redundant rows within the respective topology region. The aforementioned additional advantages of regular rows being less prone to faults are also attained if redundant rows within each topology region are arranged at both edges of the relevant region, that is to say not only on both sides of each twist area but also at each edge of the cell array which is parallel to the rows.

There is similarly little limitation of the invention to the twist patterns shown by way of example in the FIGS.; it can be applied to memory cells having any desired twist patterns and any number of twist areas. This also applies to twists in which the two wires of a column line do not intersect one another, but instead intersect wires of other column lines. With some twist patterns, particular data topologies may recur one or more times after a certain number of twist areas. In such cases, the “region” of the relevant topology is divided into two or more mutually remote sections, as it were. The elements of the subset of the redundant rows which is associated with this topology may then either all be situated in one of these sections or may be distributed over the individual sections.

We claim:

1. A digital memory circuit, comprising:
at least one cell array with a multiplicity of memory cells in a matrix arrangement of rows and columns, said cell array having edges extending parallel to said rows;
said rows and columns including regular rows and regular columns defining a nominal memory capacity of said cell array, and redundant rows of memory cells replacing faulty regular rows;
said columns having at least one subset of columns wherein wires of column lines used for accessing said memory cells intersect one another at locations between said edges of said cell array parallel to said rows, thereby changing a data topology changes at said locations; and
said redundant rows of memory cells forming separate subsets arranged in regions of different data topology in said cell array, such that, for each data topology, a subset of said redundant rows is available with a corresponding data topology.

2. The digital memory circuit according to claim 1, wherein at least some elements of each subset of redundant rows arranged in a region adjacent to a respective said edge of said cell array extending parallel to said rows are arranged directly adjacent to said edge.

3. The digital memory circuit according to claim 1, wherein at least some elements of each subset of redundant rows arranged in a region between two adjacent areas extending parallel to said rows, in which areas column line wires intersect one another, are disposed directly adjacent to at least one of said areas.

4. The digital memory circuit according to claim 1, wherein said rows and columns further include a plurality of redundant columns of memory cells replacing faulty regular columns; and said redundant columns are arranged as two separate blocks at mutually opposite edges of said cell array extending parallel to said columns.
